(19) United States
(12) Patent Application Publication
(10) Pub. No.: US 2007/0096764 A1
(43) Pub. Date: May 3, 2007

(54) Immersion exposure apparatus and method of manufacturing semiconductor device

(76) Inventors: Takuya Kono, Yokosuka-shi (JP); Tatsuhiko Higashiki, Fujisawa-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/586,527

(22) Filed: Oct. 26, 2006

(30) Foreign Application Priority Data
Oct. 27, 2005 (JP) 2005-313256

(51) Int. Cl. G01R 31/26

(52) U.S. Cl. 324/765

(57) ABSTRACT

An immersion exposure apparatus includes a substrate holding unit which holds a substrate to be exposed, a projection lens provided above the substrate holding unit to supply exposure light to the substrate held on the substrate holding unit, a liquid supply unit which supplies a liquid to an area between the substrate held on the substrate holding unit and the projection lens, and a structural unit which surrounds the substrate holding unit and which is configured to supply an interposer to an area between the structural unit and the substrate held on the substrate holding unit.

### CROSS-REFERENCE TO RELATED APPLICATIONS

This application is based upon and claims the benefit of priority from prior Japanese Patent Application No. 2005-313256, filed Oct. 27, 2005, the entire contents of which are incorporated herein by reference.

### BACKGROUND OF THE INVENTION

1. Field of the Invention

The present invention relates to an immersion exposure apparatus and a method of manufacturing a semiconductor device.

2. Description of the Related Art

The reduced size and increased integration level of semiconductor devices have made what is called immersion exposure important; the immersion exposure is a technique for carrying out exposure with a liquid such as water interposed between a substrate to be exposed and a projection lens in an exposure apparatus. However, with the immersion exposure, the liquid remaining on the surface of the substrate may disadvantageously flow out of the substrate, which contaminates the apparatus.

To solve this problem, Jpn. Pat. Appln. KOKAI Publication No. 2004-193252 proposes a structure that prevents the liquid from flowing out. However, this proposal poses various problems because the structure is fixed to the apparatus. For example, when the substrate is set on a substrate holding unit (wafer chuck or the like), the structure disadvantageously constitutes an obstacle to the setting of the substrate.

Thus, with the immersion exposure, the liquid for the immersion exposure may disadvantageously contaminate the apparatus. However, not all the conventional immersion exposure apparatuses comprise appropriate structures for preventing contamination.

### BRIEF SUMMARY OF THE INVENTION

According to a first aspect of the present invention, there is provided an immersion exposure apparatus comprising: a substrate holding unit which holds a substrate to be exposed; a projection lens provided above the substrate holding unit to supply exposure light to the substrate held on the substrate holding unit; a liquid supply unit which supplies a liquid to an area between the substrate held on the substrate holding unit and the projection lens; and a structural unit which surrounds the substrate holding unit and which is configured to supply an interposer to an area between the structural unit and the substrate held on the substrate holding unit.

According to a second aspect of the present invention, there is provided a method of manufacturing a semiconductor device using the immersion exposure apparatus according to claim 1, the method comprising: holding the substrate on the substrate holding unit; supplying the interposer from the structural unit to an area between the substrate held on the substrate holding unit and the structural unit; supplying a liquid from the liquid supply unit to an area between the substrate held on the substrate holding unit and the projection lens; and supplying exposure light to the substrate through the projection lens with the liquid interposed between the substrate held on the substrate holding unit and the projection lens.

### BRIEF DESCRIPTION OF THE SEVERAL VIEWS OF THE DRAWING

FIG. 1 is a diagram schematically showing the general configuration of an immersion exposure apparatus according to an embodiment of the present invention;

FIG. 2 is a plan view schematically showing the arrangement of a semiconductor wafer and the like according to the embodiment of the present invention;

FIG. 3 is a diagram schematically showing how the immersion exposure apparatus according to the embodiment of the present invention is used;

FIG. 4 is a diagram schematically showing a modification of the immersion exposure apparatus according to the embodiment of the present invention;

FIG. 5 is a diagram schematically showing another modification of the immersion exposure apparatus according to the embodiment of the present invention;

FIG. 6 is a diagram schematically showing still another modification of the immersion exposure apparatus according to the embodiment of the present invention; and

FIG. 7 is a flowchart showing a method of manufacturing a semiconductor device using the immersion exposure apparatus according to the embodiment of the present invention.

### DETAILED DESCRIPTION OF THE INVENTION

An embodiment of the present invention will be described below with reference to the drawings.

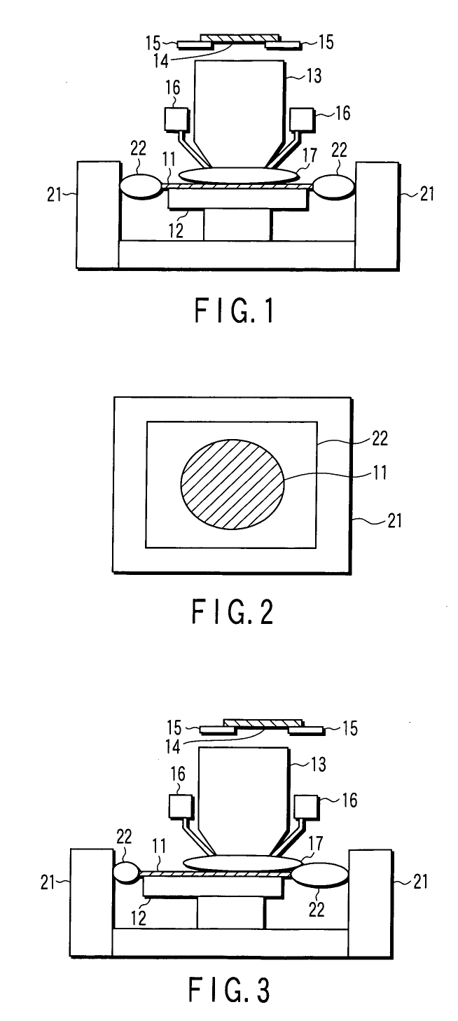

FIG. 1 is a diagram schematically showing the general configuration of an immersion exposure apparatus according to an embodiment of the present invention.

As is the case with conventional immersion exposure apparatuses, a semiconductor wafer (semiconductor substrate) 11 to be exposed is held on a wafer chuck (wafer holding unit) 12. A projection lens 13 is placed above the wafer chuck 12. A mask chuck (mask holding unit) 15 is placed above the projection lens 13 to hold a photo mask 14. The photo mask 14 is irradiated with illumination light from a light source (not shown). A mask pattern on the photo mask 14 is projected on the semiconductor wafer 11 by supplying exposure light having passed through the photo mask 14 to the semiconductor wafer 11 via the projection lens 13.

A liquid supply/recovery unit 16 supplies a liquid 17 for immersion exposure to the area between the semiconductor wafer 11 held on the wafer chuck 12 and the projection lens 13. The liquid supply/recovery unit 16 does not supply the liquid 17 to the entire principal surface of the semiconductor wafer 11 but to a partial area of the principal surface. The supplied liquid 17 can be recovered by the liquid supply/recovery unit 16. The liquid 17 is, for example, water. Resolution can be increased by carrying out exposure with the liquid 17 interposed between the semiconductor wafer 11 and the projection lens 13.

The wafer chuck 12 and the mask chuck 15 can each move (scan) relative to the projection lens 13. Moving the wafer chuck 12 and mask chuck 15 to a desired position for exposure enables the mask pattern formed on the photo mask 14 at a desired position to be projected on the semiconductor wafer 11 at a desired position. The position of the liquid 17 on the semiconductor wafer 11 also varies with the movement of the wafer chuck 12.

A structural unit 21 having a wall like outer shape is placed around the wafer chuck 12. The structural unit 21 surrounds the wafer chuck 12. The top surface of the structural unit 21 is higher than that of the semiconductor wafer 11 held on the wafer chuck 12.

The structural unit 21 can supply an interposer 22 to the area between the structural unit 21 and the semiconductor wafer 11. FIG. 2 is a plan view schematically showing the positional relationship between the semiconductor wafer 11, the structural unit 21 and the interposer 22. The interposer 22 thus interposed between the structural unit 21 and the semiconductor wafer 11 makes it possible to prevent the downward leakage of the liquid 17 flowing out of the semiconductor wafer 11. For example, as shown in FIG. 3, even if the wafer chuck 12 moves to a position where it may cause the liquid 17 to fall from the end of the semiconductor wafer 11, the interposer 22 interposed between the structural unit 21 and the semiconductor wafer 11 enables the leakage of the liquid 17 to be prevented. This makes it possible to prevent the apparatus from being disadvantageously contaminated with the liquid 17 flowing out of the semiconductor wafer 11.

The interposer 22 is usually not interposed between the structural unit 21 and the semiconductor wafer 11 but is, for example, housed in the structural unit 21. For immersion exposure, the interposer 22 projects out of the structural unit 21 toward the outer periphery of the semiconductor wafer 11. The interposer 22 is then placed between the structural unit 21 and the semiconductor 11. Thus, the interposer 22 is not always fixed and is usually not interposed between the structural unit 21 and the semiconductor wafer 11. This makes it possible to avoid the problem that when the semiconductor wafer 11 is set on the wafer chuck 12, the interposer 22 constitutes an obstacle to the setting of the semiconductor wafer 11.

Since the semiconductor wafer 11 moves together with the wafer chuck 12, the spacing between the structural unit 21 and the semiconductor wafer 11 is not fixed but varies depending on the position as shown in FIG. 3. Accordingly, the interposer 22 is controlled so that the projection amount (projection width) of the interposer 22 varies in response to the movement of the wafer chuck 12.

The interposer 22 may be, for example, a deformable flexible material. Specifically, the interposer 22 may be plastic, which maintains a shape resulting from deformation as it is, or elastomer, the shape of which changes from one resulting from deformation back to the original one when an external force is removed. The elastomer may be a thin film in which a gas or liquid is sealed. If a deformable flexible material is used as the interposer 22, the interposer 22 is deformed depending on the shape of outer periphery of the semiconductor wafer 11. This allows the interposer 22 to adhere easily to the outer periphery of the semiconductor wafer 11.

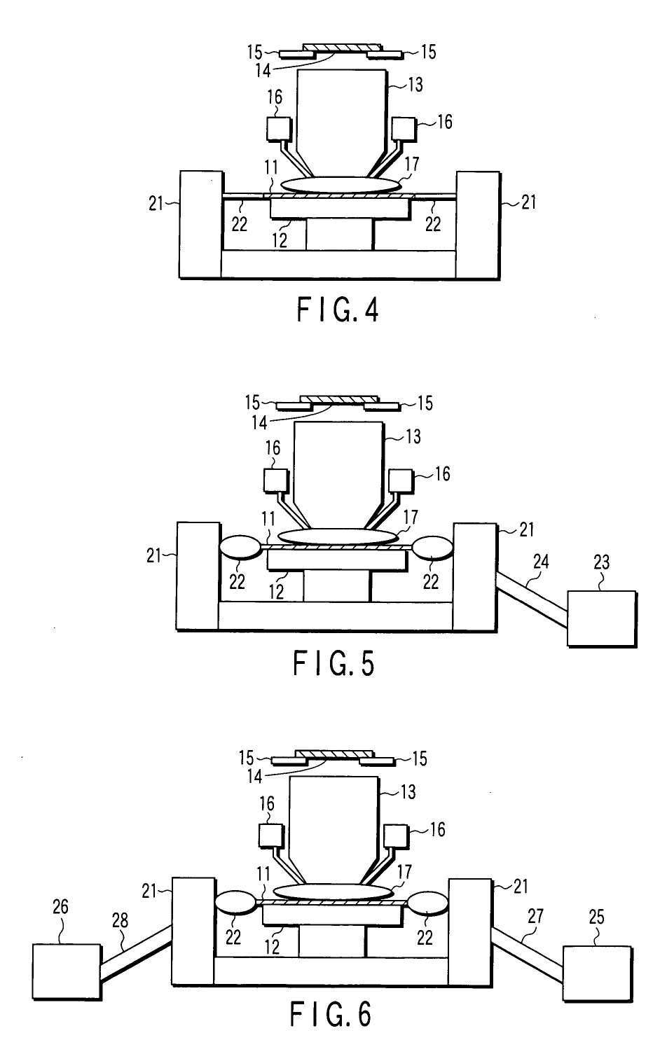

Alternatively, the interposer 22 may be a rigid material formed of metal or nonmetal instead of the deformable flexible material. For example, as shown in FIG. 4, a plate-like material can be used as the interposer 22.

A washing mechanism may be provided inside the structural unit 21 to wash the interposer 22. Contaminants such as the liquid for immersion exposure often adhere to the surface of the interposer 22. The washing mechanism provided inside the structural unit 21 enables the interposer 22 to be effectively washed after the interposer 22 has been housed in the structural unit 21.

In the above embodiment, the interposer 22 is usually housed in the structural unit 21. However, as shown in FIG. 5, a housing container 23 may be provided in addition to the structural unit 21 so that the interposer 22 can be housed in the housing container 23. In this case, the interposer 22 discharged from the housing container 23 is supplied to the area between the structural unit 21 and the semiconductor wafer 11 via a tube 24 and the structural unit 21.

As shown in FIG. 6, a supply container 25 and a recovery container 26 are provided; the supply container 25 supplies the interposer 22 and the recovery container 26 recovers the interposer 22. In this case, the interposer 22 discharged from the supply container 25 is supplied to the area between the structural unit 21 and the semiconductor wafer 11 via a tube 27 and the structural unit 21. The interposer 22 interposed between the structural unit 21 and the semiconductor wafer 11 is recovered into the recovery container 26 via the structural unit 21 and a tube 28. Thus, the separately provided supply container 25 and recovery container 26 make it possible to prevent the used interposer 22 from disadvantageously contaminating the unused interposer 22.

In the above embodiment, the interposer 22 is contacted with the outer periphery of the semiconductor wafer 11. However, a small gap may be present between the interposer 22 and the semiconductor wafer 11. In spite of the small gap, surface tension enables the liquid 17 to be held.

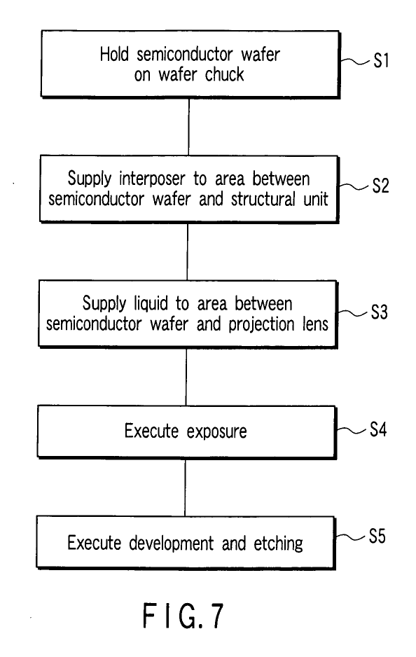

Now, with reference to the flowchart shown in FIG. 7, description will be given of a method for manufacturing a semiconductor device using the above immersion exposure apparatus.

First, the semiconductor wafer 11 to be exposed is held on the wafer chuck 12 (S1). Films to be processed (conductive film or insulating film) and a photo resist film are formed on the semiconductor wafer 11.

The structural unit 21 supplies the interposer 22 to the area between the semiconductor wafer 11 held on the wafer chuck 12 and the structural unit 21. This places the interposer 22 between the semiconductor wafer 11 and the structural unit 21 (S2).

Then, the liquid supply/recovery unit 16 supplies the liquid 17 for immersion exposure to the area between the semiconductor wafer 11 held on the wafer chuck 12 and the projection lens 13 (S3). As a result, the liquid 17 is interposed between the semiconductor wafer 11 and the projection lens 13.

Then, exposure is carried out with the liquid 17 interposed between the semiconductor wafer 11 and the projection lens 13 (S4). That is, the mask pattern on the photo mask 14 is projected on the semiconductor wafer 11 via the projection lens 13 and liquid 17. A latent image corresponding to the mask pattern is formed in the photo resist.

Then, a photo resist pattern is formed by development. The films to be processed are etched using the photo resist pattern as a mask to form a processed pattern corresponding to the mask pattern (S5).

As described above, the present embodiment interposes the interposer 22 between the semiconductor wafer 11 and the structural unit 21. This makes it possible to prevent the downward leakage of the liquid 17 for immersion exposure. Therefore, the apparatus can be prevented from being contaminated with the liquid 17.

The interposer 22 is supplied by the structural unit 21 and is not always present between the semiconductor wafer 11 and the structural unit 21. This makes it possible to avoid the problem that when the semiconductor wafer 11 is set on the wafer chuck 12, the interposer 22 constitutes an obstacle to the setting of the semiconductor wafer. Therefore, the semiconductor wafer 11 can be easily and steadily set on the wafer chuck 12. Further, since the interposer 22 is not always present between the semiconductor wafer 11 and the structural unit 21, it can be easily washed.

As a result, the productivity and yield of semiconductor devices can be improved by using the immersion exposure apparatus according to the present embodiment to manufacture semiconductor devices.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An immersion exposure apparatus comprising:
a substrate holding unit which holds a substrate to be exposed;
a projection lens provided above the substrate holding unit to supply exposure light to the substrate held on the substrate holding unit;
a liquid supply unit which supplies a liquid to an area between the substrate held on the substrate holding unit and the projection lens; and
a structural unit which surrounds the substrate holding unit and which is configured to supply an interposer to an area between the structural unit and the substrate held on the substrate holding unit.

2. The apparatus according to claim 1, wherein the interposer supplied by the structural unit contacts an outer periphery of the substrate.

3. The apparatus according to claim 1, wherein the interposer is deformable.

4. The apparatus according to claim 3, wherein the interposer is elastic.

5. The apparatus according to claim 3, wherein the interposer is plastic.

6. The apparatus according to claim 1, wherein the liquid supply unit supplies the liquid to a partial area on the substrate held on the substrate holding unit.

7. The apparatus according to claim 1, wherein the substrate holding unit is movable.

8. The apparatus according to claim 7, wherein a projection amount by which the interposer projects from the structural unit toward the substrate varies in response to movement of the substrate holding unit.

9. The apparatus according to claim 1, wherein the structural unit has a wall-like outer shape.

10. The apparatus according to claim 1, wherein the interposer is housed in the structural unit before the interposer is supplied to the area between the structural unit and the substrate.

11. The apparatus according to claim 1, wherein the interposer is housed in a housing container different from the structural unit before the interposer is supplied to the area between the structural unit and the substrate.

12. The apparatus according to claim 1, wherein the interposer supplied to the area between the structural unit and the substrate is recovered into a recovery container different from the structural unit.

13. The apparatus according to claim 1, wherein the substrate includes a semiconductor wafer.

14. A method of manufacturing a semiconductor device using the immersion exposure apparatus according to claim 1, the method comprising:
holding the substrate on the substrate holding unit;
supplying the interposer from the structural unit to an area between the substrate held on the substrate holding unit and the structural unit;
supplying a liquid from the liquid supply unit to an area between the substrate held on the substrate holding unit and the projection lens; and
supplying exposure light to the substrate through the projection lens with the liquid interposed between the substrate held on the substrate holding unit and the projection lens.
